(19) United States
(12) Patent Application Publication
(10) Pub. No.: US 2023/0288888 A1
(43) Pub. Date: Sep. 14, 2023

(54) POSITION CONTROLLER SELF-ASSESSMENT FOR DIGITAL TWIN

(71) Applicant: Samson Aktiengesellschaft, Frankfurt am Main (DE)

(72) Inventors: Christian Fiebiger, Hofheim Am Taunus (DE); Baihua Sun, Langen (DE); David Wagner-Stürz, Muehltal (DE)

(73) Assignee: Samson Aktiengesellschaft, Frankfurt am Main (DE)

(21) Appl. No.: 18/006,343

(22) PCT Filed: Jun. 22, 2021
(86) PCT No.: PCT/EP2021/066993

§ 371 Date: Jan. 20, 2023

(30) Foreign Application Priority Data
Jul. 22, 2020 (DE) 10 2020 119 379.3

(51) Int. Cl. G05B 15/02; G06F 30/28

(52) U.S. Cl. CPC G05B 15/02; G06F 30/28

(57) ABSTRACT

A positioner for a process plant, such as a chemical plant, a power plant, or a food processing plant, may include a control valve for controlling a process fluid flow of the process plant, a pneumatic actuator for actuating the control valve, and positioner electronics for determining and providing a pneumatic control signal for the actuator based on a control variable. The positioner electronics may include a signal receiving interface for receiving the control variable. The positioner electronics may include a computing device configured to determine at least one simulation parameter that characterizes a signal response of the positioner to a received control variable. The positioner electronics may include a signal output interface for outputting the at least one simulation parameter.

### CROSS REFERENCE TO RELATED APPLICATIONS

This patent application is a U.S. National Stage Application of International Application No. PCT/EP2021/066993, which claims priority to German Patent Application No. 102020119379.3, filed Jul. 22, 2020, each of which is incorporated herein by reference in its entirety.

### BACKGROUND

### Field

The disclosure relates to a positioner for a process plant, such as a chemical plant, for example a petrochemical plant, a power plant, a food processing plant or the like.

### Related Art

From DE 10 2018 133 428 A1 it is known to design a field device station, such as a control valve, of a process plant by using a so-called digital twin of the field device station in a simulation environment. In the simulation environment, a simulation is carried out on the basis of operation-specific plant characteristics of the process plant, such as the process medium, the plant environment or the like, wherein the digital twin, which is also referred to as a field device module, can be characterized on the basis of one or more field device-specific design parameters, such as a geometry parameter, a performance parameter or the like, and interact with at least one operating variable, such as a regulating variable, for example temperature, pressure, flow rate or the like.

For the simulation of the operation of the digital image of the process plant, the field device module is set to a field device to be simulated from a group of predetermined field devices, whereby associated field device-specific design parameters are defined. The field device-specific design parameters may be available as reference simulation parameters. For example, reference simulation parameters relating to a field device may be defined on a data sheet to provide field device specific design parameters for a field device module to interested professionals, such as users or research institutions. The simulation of the digital image of the process plant can serve as a basis for determining optimal operating parameters. For example, an error minimization of a control signal, reduction of levels, undershooting or overshooting of a threshold value can be specified as a boundary condition. Alternatively, a critical operating condition can be specified as a boundary condition, for example cavitation, noise level or the like. Alternatively or additionally, boundary conditions may be defined by a safety factor of the field device, for example by a consumed air volume during operation. The field device-specific design parameters on which the field device model is based define a possible parameter range, to which a concrete, for example optimal, parameter can be determined in order to fulfill one or more boundary conditions. Based on the simulation result, a concrete, physical field device can be selected or dimensioned to use it in a real process plant.

If the conditions prevailing in the real plant differ from the conditions on which the design simulation was based, this may result in that the optimum behavior calculated in the simulation is not achieved or that other boundary conditions are not met. For example, the behavior and interaction of a certain real process medium may be different from the behavior of the simulated process medium. Deviating plant conditions may exist, for example, if virtual operating parameters for the simulation environment were selected based on idealized assumptions that do not correspond to real operating conditions, or if a simulation environment was used to design a plant based on values from another plant that are not transferable due to significantly different environmental conditions. It is also conceivable that the theoretical operating conditions on which a simulation environment is based differ from the operating conditions actually set by a plant operator. Based on such differences between the real plant and the simulated plant, in the case of an abnormal behavior of a real positioner, the impression that the field device is defective may falsely arise.

DE 10 2006 046 870 A1 describes the identification and application of process models in a process control system. A process control system may include a plurality of process controllers communicatively connected to at least one host or operator workstation. The process controller may receive signals from field devices from the process control system and generate control signals that are transmitted to the field devices to control the process operation. Field devices can be, for example, valves, valve positioners, switches and transmitters (for example, temperature, pressure, and flow sensors). Some process control systems use function blocks or modules to perform control operations related to individual or groups of field devices.

The process control can be linked to a process model. Process models can be used to specify setting parameters of PID (proportional/integral/derivative) control routines using adaptive control methods, where the setting of a PID (or other) control can be updated as a consequence of changes in the process model and/or a setting rule selected by the user. However, in DE 10 2006 046 870 A1 such systems are described as rather unsuitable for practical use, because the immense effort both in terms of the required computing effort due to the high number of control loops and instruments used therein as well as the effort required to identify and validate process models and operating conditions is not in adequate proportion to the expected benefit.

DE 10 2006 046 870 A1 proposes to use a data acquisition function with routines for automatic acquisition, collection or other treatment of operational state data, and a model identification module that generates a statistical data collection of preconfigured parameters that are used in a simulation environment to determine parameters for a control loop setting based on them. Therein, a set of process models shall be generated as a process model history to provide a representation of an online performance of a control loop. The process models shall be generated by a routine embedded in the process control routine. A new process model shall be generated triggered by an event, for example in case of a setpoint change or a fault. The proposed method reduces a manual effort for the determination of models, but at the same time increases the computational effort immensely. Various approaches exist for optimizing the design and the control and/or regulating behavior of positioners in process plants. In many cases, however, it turns out to be problematic that in practice the data required for an optimization in a real plant are not available or that the computing capacities required to perform an optimization cannot be provided.

WO 2019/012121 A describes a method for providing and executing self-optimizing functions for a field device. For example, a set of functions can form a system model that is configured to learn the characteristics of a technical system. To this end, an error in the comparison between observed target values and expected target values can be calculated with the help of a model execution software that compares the target values. For example, an estimated target value can be calculated based on input variables and model parameters, and an error in comparison between the true target value and the predicted value can be measured using a loss function. With the help of a back calculation subgraph, calculations for training, i.e., updating the model parameters, can be given. This should be applicable to a wide variety of industrial systems. The use of self-optimizing control algorithms requires, on the one hand, a high computing power in individual field devices. On the other hand, such a system is always subject to the risk that the control parameters determined on the basis of the self-optimization may be inherently faulty or that a faulty plant behavior is caused in interaction with the operating conditions of a process plant, wherein a control by a control station or the like is not provided.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 a schematic representation of a process plant with a plurality of positioners according to an exemplary embodiment of the present disclosure.

FIG. 2 a schematic representation of signal sequences of a positioner according to an exemplary embodiment of the present disclosure.

FIG. 3 a schematic representation of a positioner according to an exemplary embodiment of the present disclosure.

FIG. 4 a schematic view of a grey box model in a virtual image of a positioner according to an exemplary embodiment of the present disclosure.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

An object of the disclosure is to provide a positioner which overcomes the disadvantages of the prior art, in particular supports a safe and optimized operation of a process plant safely and while using low computing and/or data transmission effort.

Accordingly, a positioner for a process plant, such as a chemical plant, for example a petrochemical plant, a power plant, for example a solar thermal power plant, a food processing plant, for example a brewery, or the like is provided. The positioner comprises a control valve for adjusting a process fluid flow of the process plant. The control valve may be, for example, a binary on/off valve or a valve with a variably adjustable flow width. The positioner further comprises a particularly pneumatic actuator for actuating the control valve, and a positioner electronics for providing a pneumatic control and/or regulating signal for the pneumatic actuator depending on a control variable. In an exemplary embodiment, the control variable may be an analog control signal or a digital control signal. An analog control signal can be, for example, a 4-20 mA signal. A digital control signal can be, for example, a pulse-width modulated control signal according to the HART protocol. The positioner electronics can comprise digital and/or analog electronic components.

The positioner electronics can comprise as digital components, for example, a data carrier with commands stored on it and/or a data carrier with parameters stored on it or the like. The actuator electronics comprises a signal receiving interface for receiving the control variable. A positioner electronics may comprise a computing device. For example, the positioner electronics may comprise a data carrier with commands stored on it, wherein the commands, when executed by one or more processors of the computing device, set up the computing device to perform a control function, a regulation function, and/or a simulation function. The positioner electronics may comprise a storing structure that provides data to specify at least one simulation parameter and/or at least one simulation structure with respect to the positioner. The storing structure may be given in the form of an array of a table or a matrix and may specify a plurality of parameters and/or structures, in particular a history at different times of certain simulation parameters and/or simulation structures, in particular of the same type. The storing structure may be accessed via a first index to retrieve a simulation parameter. The data of the storing structure can alternatively or additionally, be defined as functional data and, for example, define an entry point of a function which generates the respective simulation parameters when called. Further designs of the storing structure are conceivable and can be adapted both to a hardware or software structure of the positioner electronics, the field device and/or a simulation environment.

The positioner electronics comprises a computing device which is configured to determine at least one simulation parameter which characterizes a signal response of the positioner to a received control variable. The positioner electronics further comprises a signal output interface for outputting the at least one simulation parameter. The positioner electronics may be configured to output at least one simulation parameter by means of the signal output interface of the positioner electronics. The signal response of the positioner can be defined, for example, as a mathematical function which, depending on at least one control variable and depending on at least one or more predetermined simulation parameters, for example a reference simulation parameter, a historical simulation parameter or the like, determines a result which correlates, for example, to an operating variable of the process plant, in particular of the positioner. An operating variable, such as a regulating variable, can be, for example, a temperature, a pressure, a flow rate or the like, in particular related to the process fluid, of the process plant, in particular in the upstream feed and/or in the downstream wake of the control valve. An operating variable can in particular designate the position of the control valve, for example a travel of a valve member relative to a valve seat, a travel position of a lifting rod, for example relative to a reference point of the housing, such as a yoke or a lantern of the control valve, and/or a travel position of the pneumatic actuator. An operating variable can be the pneumatic control and/or regulating signal of the positioner electronics for the pneumatic actuator, in particular a pneumatic pressure in a control chamber of the pneumatic actuator and/or a supply line of the actuator. The simulation parameter determined by the positioner electronics may be referred to as realistic simulation parameter. In an exemplary embodiment, the simulation parameter corresponds to an actually measured signal response of the positioner to a received control variable.

A positioner that is configured to output a newly determined simulation parameter by means of a signal output interface makes it possible to provide a master display or central computer unit of a process plant that is superior to the positioner. The master display or other computer unit performs a simulation with one or more realistic simulation parameters using a virtual image of the process plant, parts of the process plant or the positioner. With the realistic simulation parameters, a virtual image can be the basis for the simulation so that the simulation is based on realistic simulation data and not on hypothetical simulation parameters that lead to simulation results that deviate significantly from realistic signal responses. In this way, it is possible by means of the virtual image of a simulated plant or parts thereof to implement better simulation results with respect to the optimized design of the plant and its components, for example, to provide optimal control variables to the positioner with respect to a process of the process plant.

According to one embodiment, the positioner electronics comprises at least one data storage for the at least one simulation parameter, wherein the data storage comprises at least one stored reference simulation parameter for the at least one simulation parameter and/or wherein the data storage is configured to hold several historical simulation parameters determined at different times. A reference simulation parameter can, for example, be a simulation parameter which corresponds to a specification of a data sheet and/or which characterizes the behavior of a typical positioner of a certain design under ideal conditions. A reference simulation parameter can be, for example, a specific ideal parameter in a range of design parameters of a positioner family determined according to DE 10 2018 133 428 A1. A reference simulation parameter can be a simulation parameter determined, in particular under ideal conditions on a test bench, with the control valve of the positioner. A reference parameter can be distinguished from a realistic simulation parameter in particular by that a realistic simulation parameter is or was determined on the positioner during use, in particular operational use, in the process plant, whereas a reference simulation parameter may have been determined, if necessary purely theoretically, outside the process plant under consideration, in particular before the positioner was put into operation for the first time. A reference simulation parameter may have been calculated using exclusively a theoretical mathematical model, in particular under ideal conditions.

Historical simulation parameters were determined in particular by the positioner electronics at a point in time in the past. In an exemplary embodiment, historical simulation parameters may be identified by particularly sequential numbering, a date and/or time stamp or the like to differentiate the various historical simulation parameters from each other and from the current realistic simulation parameter. In particular, the identification of the historical simulation parameters may be distinct with respect to the temporal sequence of the historical simulation parameters recorded one after the other in time. For this purpose, a consecutive ascending numbering may be sufficient. Historical simulation parameters are determined in particular during use of the positioner, in particular operational use of the positioner, in the process plant. For example, historical simulation parameters can be determined regularly, at predetermined times and/or predetermined events, and stored in the data storage of the positioner electronics as historical simulation parameters. For example, realistic simulation parameters can be determined by the positioner electronics of the positioner at regular time intervals, such as hourly, daily, weekly, monthly, or the like (initially as current realistic simulation parameters) and stored simultaneously or subsequently as historical simulation parameters. Historical simulation parameters can be generated by the positioner electronics, for example, when realistic simulation parameters are regularly recorded, when the positioner performs a particularly specific diagnostic function, in particular a partial stroke test and/or a full stroke test.

According to a further development of a positioner, the computing device can be configured to calculate a virtual signal response of the positioner based on a received control variable and at least one historical simulation parameter and/or at least one reference simulation parameter, and to compare the calculated virtual signal response with a signal response detected by the positioner, in particular by means of sensors. In particular, the positioner comprises an inner control or an inner regulating section, which may in particular comprise a forward section of a valve position control or regulations, an actuator and a control valve. In an exemplary embodiment, the valve position control and/or regulation is realized by the positioner electronics, in particular its computing device. The positioner electronics can be configured to map a control variable supplied to it onto a pneumatic control signal for the pneumatic actuator. The actuator actuates the control valve so that it takes a valve position. The spatial valve position can be defined, for example, by a rotation angle or a linear position. The position of the control valve can be detected by a suitable position sensor and made available to the positioner electronics, for example as a scalar position value. If the control value of the positioner electronics is provided to a reference element, for example an internal reference element, an internal control system or control loop can be closed. In addition to an inner control or regulating system, the positioner electronics according to this embodiment can comprise at least one, in particular two, further function blocks. For example, the computing device of the positioner may be configured such that the computing device comprises a first computing module, which may be referred to as simulation module, for a simulation for determining a virtual signal response on the basis of a reference simulation parameter and/or at least one historical simulation parameter and the received control variable. Alternatively or additionally, the computing device may be configured to comprise a second computation module, which may be referred to as an adaptation module, for determining a realistic, for example updated or adapted, simulation parameter with respect to the positioner. The computing device may be configured to perform a simulation module based on a grey-box model. A so-called grey-box model can be used to numerically approximate the behavior of the inner forward section or inner control and/or regulating system for converting the control variable into a signal response, in which case the control variable of the positioner electronics can be delivered to the grey-box model.

The simulation with the grey-box model would then generate a virtual output value (a virtual signal response) that provides an approximation for the output value respectively signal response of the real positioner. The Grey-Box model determines the virtual signal response considering at least one historical simulation parameter or reference simulation parameter. The real signal response can be detected by a sensor, for example a valve position sensor, of the positioner.

The adaptation module implemented by the computing device may be configured to perform an adaptation of the simulation module, for example of the grey box model, to reduce a deviation, in particular a numerical difference, between the virtual signal response and the real signal response. For this purpose, the adaptation module can be configured to determine at least one current and/or realistic simulation parameter by recalculating a simulation parameter or by determining an updated realistic simulation parameter based on a reference simulation parameter or a historical simulation parameter in such a way that the computing device with the simulation module achieves a better approximation, for example a smaller deviation, in particular a smaller numerical difference, between the real signal response and the virtual signal response, on the basis of the updated simulation parameter determined by means of the adaptation module.

According to a further development of the positioner, the computing device is configured to detect a deviation, in particular a difference, between the detected real signal response and the modeled virtual signal response in terms of time dimension, amplitude and/or rate of change and to determine a current simulation parameter on the basis of the deviation. To detect a deviation in time dimension and/or rate of change between real signal response and virtual signal response, the positioner electronics can use a set of historical simulation parameters from a data storage and/or a series of real signal responses determined in time sequence. For example, the positioner, in particular the computing device of the positioner, may be configured to determine a series of virtual signal responses with a simulation module depending on a series of received control variables and to detect a series of real signal responses depending on the same received control variables. The adaptation module of the computing unit can be configured to compare a series of virtual signal responses detected in time sequence and real signal responses depending on, in particular, the same control variables with each other in time dimension, for example to determine whether the real signal response is faster or slower in time dimension than the virtual signal response, and to update at least one simulation parameter based on the result of this comparison. For example, based on an idealized reference simulation parameter or outdated historical simulation parameter, the simulation module may expect a faster virtual signal response with respect to a change in a control variable, for example a response to a step signal, than the corresponding real signal response indicates. This may be the case, for example, if the dynamic friction coefficient of the control valve differs statically compared to an initial value or an ideal value. By comparing a time sequence of virtual signal responses and real signal responses with each other, the adaptation module can detect whether the rate of change assumed as a simulation parameter for the virtual mapping corresponds to the real change rate or whether there is a significant deviation. For example, in a pneumatic positioner with spring return, the real spring constant and the spring constant assumed as a simulation parameter can be unequal, which manifests in that a corresponding difference between the rate of change of a virtual signal response related to the operating variable control position and the corresponding real signal response can be seen. A deviation, in particular a difference, between a detected real signal response and a virtual signal response can be made with the help of a comparison of multiple historical real and virtual signal responses.

According to a further development, the positioner electronics can be configured to output a current simulation parameter by means of the signal output interface if the positioner electronics detects a deviation, in particular a difference, when comparing a current simulation parameter with a historical simulation parameter or a reference simulation parameter. In particular, the positioner electronics can be configured to output a current simulation parameter only if a deviation, in particular a difference, between the current simulation parameter and a historical simulation parameter or a reference simulation parameter has been detected. In this way, it can be ensured that the positioner communicates changed simulation parameters to a remote computer, such as a central computer of a process plant, in a timely manner, so that the virtual mapping of the positioner of a simulation environment can be performed with realistic simulation parameters. If necessary, it can be achieved that a low available bandwidth for data transmission, for example, is only slightly burdened by the output of updated simulation parameters.

According to an exemplary embodiment, the at least one simulation parameter is selected from a list comprising dead time, discretization, static control and/or regulating deviation (e.g., proportional gain for (Gain)), characteristic curve and/or gradient (e.g., time constant) respectively proportionality factor between a control variable, such as an input current, and an operating variable, such as a control position. A discretization can describe a difference in time direction and/or amplitude direction between a prevailing static output operating value, for example a stationary actual valve position, and a next possible other operating value, for example as a result of static friction and system inertia, starting from the output operating value. With respect to the characteristic curve, a simulation parameter may describe, for example, the P (proportionality), I (integration), and/or D (differentiation) factor of a PID controller, such as a PID control module implemented by a computing device. It should be clear that another, for example a P controller, may be characterized by one or a few factors, respectively only one P factor. A two-point controller and/or a three-point controller may be characterized by a characteristic curve which, depending on the value or a development of a control variable relative to a first and/or second threshold value, characterizes the corresponding control response. For combinations of different controller types, it is conceivable that simulation parameters corresponding to the different control types are provided for different controller ranges. Alternatively or additionally, it is conceivable that a characteristic curve is characterized as, for example, tabular correlations between input values (control variables) and output values (operating variables).

According to another exemplary embodiment, which can be combined with the previous ones, the positioner electronics can be configured so that the pneumatic control signal is provided depending on a control variable according to a control and/or regulating structure, wherein the positioner electronics is configured to output at least one simulation parameter with respect to a particularly changed control and/or regulating structure. For example, a simulation parameter may name the control and/or regulating structure(s) that the positioner electronics uses according to a predetermined classification. For example, a first name may be predetermined for a PID control structure, a second name for a PI control structure, a third name for a P control structure, and a fourth name for a two-point control structure. It should be clear that the above listing of different controller structures is purely exemplary and not limited to the aforementioned controller structures.

According to one embodiment of a positioner which can be combined with the previous ones, the signal output interface and the signal receiving interface are connected with a common signal transmission line, in particular a 4-20 mA line, wherein the signal receiving interface is configured to receive the control variable by means of the signal transmission line and wherein the signal output interface is configured to output the at least one simulation parameter by means of the signal transmission line. The positioner set up in this way can easily use existing communication means of the process plant to communicate updated simulation parameters to a computer remote from the positioner.

According to another embodiment of the positioner optionally combinable with the previous embodiment, the signal output interface comprises a display unit, such as an LCD display, for optically outputting the at least one simulation parameter. For example, the positioner may be configured to optically output at least one or more current realistic simulation parameters on a display unit of the positioner in reaction to a user input, in particular on the positioner, for example by control buttons of the positioner. If the positioner has not yet detected any realistic simulation parameters, it can be configured to output stored reference simulation parameters in reaction to an operator command by means of the display unit.

According to a further embodiment of a positioner, the output interface is configured to output the at least one simulation parameter, in particular a plurality of simulation parameters, with a data transmission rate of no more than 1200 bit/s, in particular no more than 600 bit/s or no more than 300 bit/s. Such a design of the output interface ensures that when the positioner is used in an existing infrastructure of a process plant, the possibly low possibilities for data transmission from one or more positioners to another computing unit, in particular a central master display, are within an acceptable low data volume.

According to a further aspect, the disclosure relates to a process plant, such as a chemical plant, a power plant, a food processing plant or the like, with a plurality of positioners configured as set forth above.

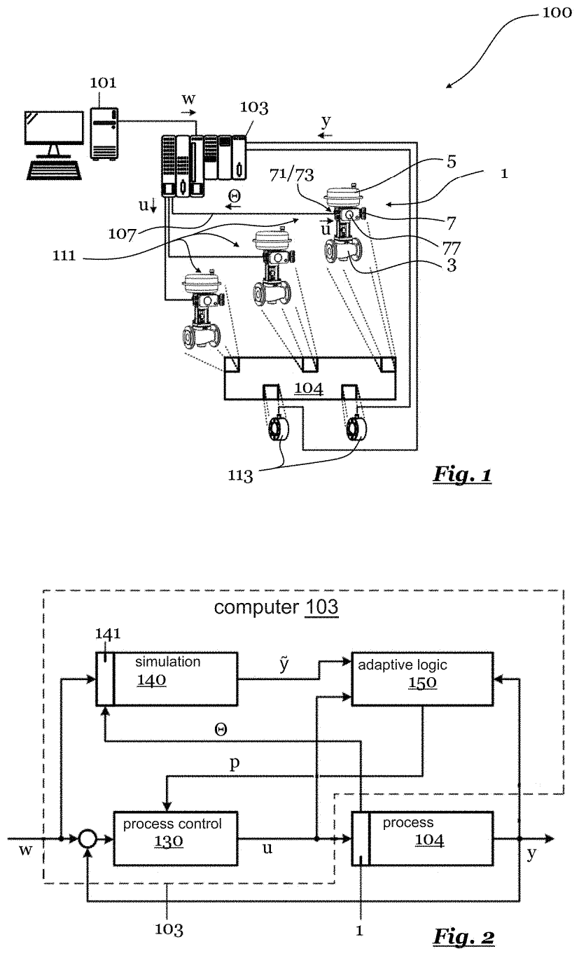

FIG. 1 shows a schematic representation of a process plant with several field devices, of which at least one can be designed as a positioner 1 according to the disclosure. The process plant 100 comprises a technical control infrastructure for monitoring and controlling a technical process. The process plant 100 comprises a control system with a control station computer 101 and a process computer 103. The process plant 100 comprises active field devices 111 and passive field devices 113 connected to the process computer 103.

Active field devices 111 are field devices, such as the positioner 1, which are provided for intervention in the technical process during operation of the process plant 100. Active field devices 111 comprise regulated and/or unregulated (controlled) control valves, shut-off valves and pumps.

Passive field devices 113 do not interfere with the technical process. Examples of passive field devices 113 are sensors. Sensors 113 may, for example, determine operating variables related to the process plant, particularly related to a process fluid and/or an auxiliary energy fluid, such as pneumatic air, of the process plant 100. For example, a sensor 113 may detect a pressure, for example a static or dynamic pressure, a temperature, a flow rate, for example a volume flow rate or a flow velocity, of the process fluid or an auxiliary energy fluid as operating variable of the process plant.

The operating behavior of individual field devices 111, 113, in particular of the positioner 1, interacts with media and parts and components of the process plant 100 and may be considered as a part of the process 104 realized in the process plant.

In the process plant 100 shown in FIG. 1 as an example, the control station computer 101 can execute an operating program with which a set of reference variables w for describing a target state of the process is generated and transmitted to a process computer 103. The operating program may, for example, be controlled by a user input.

The process plant 100 may comprise a plurality of passive field devices, in particular sensors 113, transducers and/or state sensors, such as contact sensors, to monitor the effect of the active positioners 111 on the process 104. The sensors 113 may serve to detect an actual state of the process plant. A sensor 113 may transmit at least one measured value to the process computer 103 as a regulating variable y.

In the process plant 100, a control variable u can be transmitted to an active field device, as exemplified here by the positioner 1, to transmit to the field device a specification with regard to a setting to be performed. For example, a control variable u can be transmitted to an active field device 1 by the control station computer 103, to achieve that the positioner 1 acts on the process 104 in such a way that the at least one regulating variable y is adjusted, in particular adapted, in accordance with a reference variable w transmitted by the control station computer 101 and the process computer 103. Such an action may be generally referred to as process regulation.

The positioner 1 according to the disclosure realizes an active positioner that comprises a control valve 3 for adjusting a process fluid flow, a pneumatic actuator 5 for actuating the control valve 3 and positioner electronics 7 for transmitting a pneumatic control signal to the pneumatic actuator 5. The positioner electronics 7 is configured to adjust the pneumatic control signal for the pneumatic actuator 5 depending on the at least one received control variable u. The positioner 1 can be used to control an inflow or outflow of process fluid in the process plant 100. In an exemplary embodiment, the electronics 7 may include processing circuitry configured to perform one or more functions and/or operations of the electronics 7. In an exemplary embodiment, one or more components of the electronics 7 may include processing circuitry configured to perform one or more respective functions and/or operations of the component(s).

A control variable u can generally qualitatively and/or quantitatively specify the type, intensity, timing and/or duration of an influence for the process plant by a specific active field device 111. It is conceivable that a positioner may act on the process 104 in several different ways, and correspondingly different control variables u may be provided to the positioner for this purpose.

A signal transmission line 107 is provided for transmitting the control variable u from the process computer 103 to the positioner 1. The signal transmission line 107 can be realized in particular as a 4-20 mA or 0-20 mA line, in particular to provide a control variable as a 4-20 mA current signal from the process computer 103 to the positioner 1. The control electronics 7 of the positioner 1 can, for example, be configured to provide a pneumatic control signal for the pneumatic actuator 5 depending on the amplitude of the control variable, in particular proportional to the amplitude of the 4-20 mA signal. The pneumatic control signal for the pneumatic actuator can be, for example, a pressure or a volume flow. The positioner 1 can comprise an optical display unit 77, for example in the form of an LCD display, on which a simulation parameter can be output.

The control station computer 101 and/or the process computer 103 or another computer system, not shown in more detail, may be configured to perform a simulation that represents a virtual image 140 of the process plant 100 or of parts or components of the process plant. An example of such a simulation may be a method for designing a field device station as described in DE 10 2018 133 428 A1.

FIG. 2 schematically shows a circuit diagram illustrating the function of the process computer 103 and its interaction with the process 104 in the process plant 100. As previously described, the process computer 103 comprises a process regulation 130 which receives at least one reference variable w from a control station computer 101 and at least one regulating variable y from at least one sensor 113 with respect to the process 104 from the process plant 100. The process regulation 130 determines a control variable u based on a deviation between the reference variable w and the regulating variable y, which is transmitted by the process computer 103 to at least one component in the process plant, such as the positioner 1. It should be clear that a process computer 103 typically processes a plurality of regulating variables y to transmit a corresponding plurality of control variables to a plurality of components, generally active positioners 111, in the process 104. In the present exemplary representation, simplified reference is made to only one active positioner 111. In a particularly adaptive simulation with respect to a plurality of different active field devices 111 of a process plant 100, for its individual active field devices 111 a respective individual set of regulating variable, control variable, controller parameter, model regulating variable, model parameter, etc. can be used, wherein the different variables, parameters, etc. can be designated by a respective common index related to the active positioner, such as 1, 2, 3, . . . i.

In addition to process control 130, the process computer 103 may perform a simulation 140 based on a virtual image of a process plant, parts of the process plant, or components of the process plant. For example, the simulation calculation 140 may process the actual reference variable w and/or realistic regulating variables y obtained from the real process plant. In particular, the simulation 140 may comprise a virtual image 141 of the positioner 1. Based on the reference variable w, the simulation 140 performed with the process computer 103 determines a model regulating variable \tilde{y}, that should correlate to the real regulating variable y.

The data path for transmitting simulation parameters z from the positioner 1 to a reference model 140 can correspond to an existing data path 107 between the process computer 103 and the positioner 1. The process computer 103 further comprises an adaptation logic 150 which receives as input values at least one model regulating variable \tilde{y}, at least one control variable u corresponding thereto. The adaptation logic 150 can be configured to determine at least one controller parameter p and to apply this to the process control 130 to improve the process control 130 by means of an optimization function. The controller parameter p may be determined by the adaptation logic 150 by means of a deviation between the real regulating variable y and the model regulating variable y, with the aim that the process control 130 generates a control variable u in the future with the control parameter p specified by the adaptation logic 150, so that the real regulating variable y has a smaller deviation from the model regulating variable \tilde{y}.

In a process plant with a positioner 1 according to the disclosure, the positioner 1 can send at least one realistic simulation parameter θ from the process 104 to the process computer 103. The process computer 103 may adjust the virtual image 141 of the positioner 1 based on the realistic simulation parameter u. By adapting the virtual image 141 of the positioner 1, the reference model 140 is adapted in the sense of improving the reference model 140 by approximating the simulated behavior of the reference model 140 to the real behavior of the process 104.

A process computer 103 can, for example, be equipped with a simulation module 140 and an adaptation logic 150 to be able to adapt the control 130 to changed ambient conditions of the process plant 100. For example, optimal control 130 for a process 104 in a process plant 100 may require different process parameters p when ambient temperatures are high in summer, than when ambient temperatures are low in winter. A process that comprises behavior that experiences a dependence on absolute time may generally be referred to as a non-time-variable process. Non-time-variable processes exist, for example, when process situations that start in exactly the same state develop systematically differently depending on the absolute time of the start.

Another example of an advantageous use of a process computer 103, whose control is temporarily preset by an adaptation of an adaptation logic 150 with variable process parameters and fit to such cases where, for example, as a result of a changed control by the control station computer 101, a variable behavior of the reference variable is present. For example, a control station computer 101 may be configured to preset a reference variable w that has a low dynamic range over a long period of time. If the configuration of the control station computer 101 is changed such that the reference variable has a high dynamic response over a small period of time, it may be useful or even necessary in a stable process control of the process 104 to adjust the parameters of the control 130. For example, in a control 130 configured as a PID controller, whose P, I, and/or D portions are adapted to a changed dynamic behavior of the reference variable w by means of the adaptation logic 150.

More fundamental changes could be a change between a first controller structure, for example a PID controller structure, to a second controller structure, for example a two-point controller structure or a three-point controller structure, or vice versa.

The simulation module 140 or reference model of the process computer 103 comprises, as described above, a virtual image 141 that may be referred to as a digital twin with respect to the positioner 1 in the process plant 100. The virtual image 141 of the positioner 1 may be implemented as a submodel within a more complex reference model, wherein the reference model 140 may virtually represent the entire process plant 1 or a portion of the process plant 100 within which the positioner 1 is located. The reference model 140 may comprise several submodels for different active field devices 111. A sub-model relating to an active field device 111 may be implemented by a deterministic calculation formula in a digital computing unit in a computing arrangement of the process computer 103. For example, a sub-model may be implemented as a so-called grey-box model. A virtual image 141 of a real, active field device 111, in particular of the positioner 1, may be implemented as a deterministic calculation formula that maps the time course of a quantified control variable u to an operating variable y, for example an absolute control position or a relative control position (for example corresponding to a 0-100% scale with respect to an opening width of the control valve).

FIG. 3 shows a schematic representation of the positioner 1 according to the disclosure. As essential components, the positioner 1 comprises a control valve 3 for adjusting a process fluid flow, an actuator 5 for actuating the control valve 3, and positioner electronics 7 for providing a control signal, in particular a pneumatic control signal s, depending on a control variable u.

The positioner electronics 7 can, for example, be configured as digital positioner electronics with a computing unit 70 for executing at least one program or module, in particular several programs or modules. In an exemplary embodiment, the computing unit may comprise a processor 75, a signal receiving interface 71, a storage 76, and a signal output interface 73. Furthermore, the positioner electronics 7 may include at least one control and/or regulating interface with at least one control and/or regulating signal output 74 for outputting the particularly pneumatic control signal s to the particularly pneumatic actuator 5. Furthermore, the positioner electronics 7 may include at least one regulating variable input 72, which is configured, for example, with a position sensor 13 or another sensor (not shown in detail) for receiving at least one device regulating variable, for example an x.

The positioner electronics 7 is configured to generate the control signal s depending on a control variable u supplied to it and a device regulating variable x supplied to it. To generate the control signal s, the computing unit 70 may implement a control and/or regulation module or program 30 using a processor 75 and a memory 76. The computing unit 70 of the positioner 1 may be configured to detect a control variable u and a device regulating variable x, or a difference value calculated by a difference element between the device regulating variable x and the control variable u, and to perform a routine that determines the control signal s, based on a control and/or regulation function 30 stored in the memory 76 of the computing unit 70. The control signal s can be transmitted to the actuator 5 by the positioner electronics 7 with the control and/or regulation output 74. The control and/or regulation output 74 may comprise an electro-pneumatic transducer for providing a pneumatic control signal. The output 74 may alternatively be configured to provide an electrical control signal for an electrical actuator, for example an electric motor, as an analog or digital electrical signal, for example PWM signal (not shown in more detail).

The actuator 5 actuates the control valve 3, for example by means of a control rod or control shaft. The position of the control valve 3 can be detected by means of a position sensor x and reported to the positioner electronics 7 as a device regulating variable x. The device regulating variable x can describe an absolute or relative position of the control valve 3, as described previously. In the positioner according to the disclosure, the positioner electronics 7 is further configured to determine at least one simulation parameter θ relating to the positioner 1. For this purpose, the computing unit 70 of the positioner electronics 7 may comprise a plurality of functions or modules, in particular simulation modules 40 and an adaptation module 50.

The computing device 70 is configured to implement a simulation module 40 that receives as input a control variable u to calculate, based on at least one simulation parameter θ, a virtual signal response \tilde{x} corresponding to a real signal response in form of a device regulating variable x. According to one embodiment, the computing unit 70 is configured to implement that it performs a mathematical deterministic determination of a virtual signal response \tilde{x} by providing to the deterministic function the control variable u as variable as an input value. The deterministic function implemented with the simulation module 40 comprises as simulation parameters θ, for example, a dead time, a discretization and a characteristic curve, which defines a correlation between on the one hand the control variable and on the other hand the virtual device regulation value calculated as virtual signal response \tilde{x}, which corresponds to a real device regulation value x. The simulation module 40 implemented by the computing device 70 of the positioner 1 may be designed to correspond to or be identical to a virtual image 141 of the real positioner in a reference model 140 implemented in the process computer 103.

In other words, the real positioner 1 is configured to implement a virtual twin of itself by means of its own computing device 70 to implement self-checking with respect to the model behavior, i.e., the virtual signal response \tilde{x} image respectively digital twin 141 of the positioner 1 and the real signal responses x of the real positioner 1 in reaction to the same control variable u.

The computing device 70 is further configured to detect a deviation between virtual signal response \tilde{x} and real signal response x, for example, by means of an adaptation module 50. Based on a discrepancy between virtual signal response \tilde{x} and real signal response x, the adjustment module 50 can generate updated or corrected simulation parameters θ. The at least one simulation parameter θ calculated by the adaptation module 50 may optionally be stored as a historical parameter θ_{H} in the memory 76 of the computing device 70 and/or output by means of a network interface or other signal output interface 73 via a signal transmission line 107.

Such a positioner 1 is able to determine, by means of a virtual twin of itself, whether the interaction of the real positioner 1 with its environment corresponds to the interaction between the virtual image 141 of the positioner 1 in a simulation environment 140. By means of deviations between the real behavior of the positioner and the behavior of its virtual image 141, the computing device is able to adjust the simulation parameters θ defining the virtual image to achieve a more realistic virtual image. By that the positioner 1 is further configured to output the information provided by the simulation parameters by means of a signal output interface 73, the information regarding updated simulation parameters can also be communicated to other models, for example a reference model 140 implemented at a process computer 103. In this way, a reference model 140, in particular of a virtual image 141 of the positioner 1 used therein, can perform a more realistic simulation, by means of which, for example, optimized control variables u for controlling the positioner can be determined to control a process 104 more quickly, efficiently, safely and/or stably, for example, in accordance with selected optimization criteria.

From the computing unit (computer) 70, an adaptation module (adapter) 50 is implemented, for example, by the processor 75 and the memory 76. The adaptation module 50 can interpret, for example, a numerical difference or other deviation between a virtual signal response \tilde{x} and a real signal response x as a criteria regarding the quality of the simulation implemented by the simulation module 40.

The adaptation module 50 may be referred to as a calculation module for adapting the simulation parameters θ. The adaptation module 50 may be configured to adapt the simulation model selected in the exemplary situation, for example a grey-box model, in such a way that a numerical difference between the virtual signal response and the real signal response x is reduced, in particular reduced to a minimum. A number of optimization methods, for example iterative optimization methods, are known to the person skilled in the art, which can be implemented by the calculation module 50.

The simulation module 40 may be defined by a structural description of a virtual image or model of the real positioner 1 and a set of simulation parameters o. The structural description may be understood as an abstract model (for example, a modeled PID controller) that is concretized by a set of model parameters with respect to the real positioner 1. When the positioner 1 is new, the available simulation parameters θ can be provided as reference simulation parameters θ_{R}, wherein reference simulation parameters θ_{R} can be provided, for example, type-specific with regard to the real positioner as a factory setting or by means of a data sheet.

In embodiments with multiple alternative control and/or regulation structures, the model description of the control and/or regulation structure itself may be considered a simulation parameter. A model of a control and/or regulation structure may be described or identified by one or more parameters. One or more simulation parameters identifying or describing a modeled control and/or regulating structure may be stored on a memory 76 of the computing device 70 of the positioner 1 and may be transmitted via a signal output interface 73 to a higher-level simulation computer, such as with the process computer 103 exemplarily described herein.

In an exemplary embodiment, the computing device 70 is a digital computing unit. The computing device 70 can be schematically subdivided into a processor 75, a memory 76 and a network interface 73, which acts as a signal output interface. The computing unit may further comprise at least one signal receiving interface 71. The signal receiving interface 71 and/or the signal output interface 73 may comprise an analog-to-digital converter and/or a digital-to-analog converter.

In the embodiment described above, the control and/or regulating module 30 as well as the simulation module 40 and the adaptation module 50 are related to the primary effect of the positioner 1, i.e., the causal linkages between the control variable u and the regulating variable or real signal response x specified in the context of the process control. In addition to the primary effect of the positioner 1, the positioner 1 may have further secondary effects relevant to the process 104, which are to be taken into account for the control and/or regulating module 30 and/or the simulation module 40, to be able to achieve an optimized process control.

It is conceivable that a secondary effect of the positioner 1 relates to noise generation or other emission from the positioner 1. For example, as secondary effect an heat input from the positioner 1 into the process 104 may be relevant. For example, the waste heat from a positioner 1 driven by an electric actuator may be relevant to the energy consumption of an air conditioning system or to its potential to maintain a certain temperature specification at a predetermined location of a technical system 100. In such a case, the control variable u and/or the device regulating variable x may relate to a temperature.

In a positioner with compressed air operation, for example with a pneumatic actuator 5, a secondary effect can be the air consumption of the positioner 1. For example, as an operating parameter, the air consumption of the positioner 1 may be relevant, in particular depending on a desired change of the primary effect. It is conceivable that an operating parameter may relate to the air consumption of the positioner 1. A relatively high air consumption of the positioner 1 may lead to an effect, for example a fluctuation, on the compressed air supply also for other positioners. Such a change may result in an interaction that affects the operating behavior of the considered positioner 1 or other active field devices 111 of the process plant 100. For example, compressed air may be provided to multiple active field devices 111, such as shown in FIG. 1, to operate pneumatic actuators of the positioners 111. If the positioner has a particularly high compressed air consumption, for example in the case of a compressed air leakage or because the pneumatic actuator 5 of the actuator is large, possibly too large, dimensioned and requires a high compressed air volume, this can have the consequence that the volume or pressure available in the pressure supply systems drops to an actual value below an ideal value for which the field devices 111 are designed. This can have as a result, for example, that a positioner 5 in the real process plant 100 achieves a slower signal response x than expected based on, for example, ideal reference simulation parameters o_{R}, or that the control valve is not able to provide the necessary closing force to safely bring the control valve 3 into a closed state if the compressed air supply is too low. For a model referring to the air consumption of the positioner 1, the measurement of a compressed air curve over time at a throttling point could be detected as signal response x.

Another alternative for observation with a simulation model 40 could concern the statistical operating time until a next maintenance time, the discharge of combustible drive gases, the extraction of electrical power from an electrical supply device (electrical auxiliary power), or the access to the bandwidth of a particularly digital signal transmission line 107. The simulation model 3 of the positioner 1 or of the virtual image 141 of the positioner 1 can consider one or more other signal responses as an alternative or in addition to a primary effect of the positioner 1.

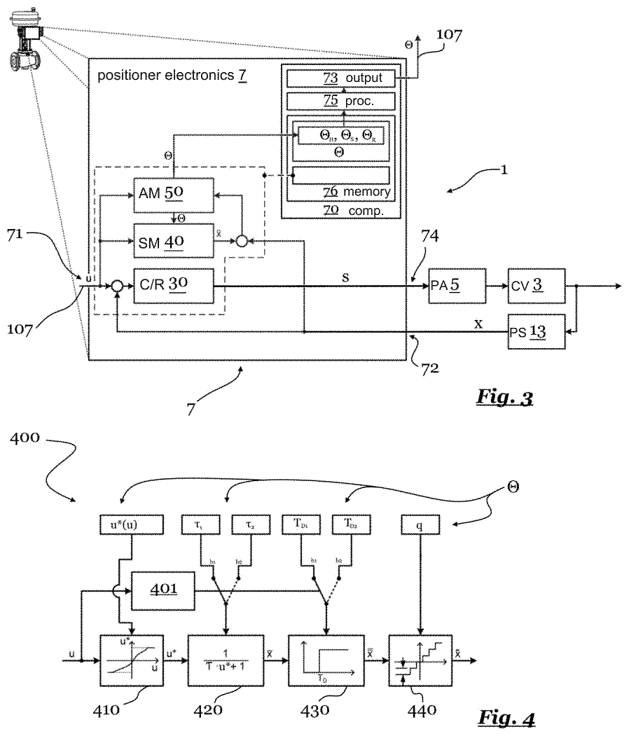

A model for simulating the exemplary positioner, for example as a virtual image 141 or as a simulation module 40, can be realized for example as a so-called grey-box model. FIG. 4 shows as an example a schematic grey-box model with respect to a positioner 1 with a pneumatic actuator 5. The grey-box model generally has the reference sign 400. The grey-box model may be implemented by the computing device 70 of the positioner 1 and/or by a computing arrangement of the process computer 103. The model 400 comprises a first routine 401 for detecting an operating mode, in particular a direction of movement of the actuator 5 (opening direction or closing direction). Many field devices 111 show a signal response with a hysteresis, which is dependent on the operating mode. The detection of the operating mode, in particular of a direction of movement, can be done, for example, by tracking the direction of the temporal change of the control variable u. Alternatively or additionally, an operating mode can be derived from the control of the compressed air supply (not shown in more detail). For particularly two (preferably exactly two) operating modes, different parameterizations of the entire grey box model can be realized.

The virtual image of the operating behavior of a positioner schematically shown in FIG. 5, for example in the form of the grey box model shown, comprises several successive calculation sections with which a supplied control variable u is mapped via several intermediate values u*, x̅ and x⁻ onto a virtual signal response \tilde{x}, which may also be referred to as the model output variable. The virtual image may comprise as calculation sections, for example, a first calculation section 410 for a static transmission profile, a second calculation section 420 for a time behavior of an inner forward path (static control and/or regulating deviation in time dimension τ), a calculation section 430 for a dead time T_{D}. The virtual image may further comprise a fourth calculation section 440 for a quantification or discretization.

Different operating modes are illustrated in the virtual image according to FIG. 5 as a first operating mode b1, for example filling, and as a second operating mode b2, for example emptying. The different calculation sections 410, 420, 430 and 440 are schematically subdivided in a structural part (shown below), which mathematically represents the general behavior of the virtual image of a positioner 1 in a more structurally defined way. Furthermore, the here four different calculation sections 410, 420, 430 and 440 (shown above) comprise one or more simulation parameters θ, which specifically with respect to the positioner 1 concretize the mathematical structural model the virtual image 141 respectively simulation module 40. It may be preferred to characterize a virtual image of a positioner 1 exclusively in such simulation parameters θ, which are to be realized for the concretization of a simulation model that is in particular generally valid, specified by a standard or an industry practice. Such a characterization exclusively of simulation parameters for a structurally specified virtual image of the positioner can be advantageous in particular if only a few aspects of the numerical calculation shall be accessible to an adaptation.

The virtual image 400 may be configured, using the operating mode identifier 410, to use simulation parameters θ dependent on a particular detected operating mode b1 or b2. This may be used to adjust the simulation parameters θ separately for different operating modes b1, ultimately b2.

Using the first calculation section 401 with respect to the static transmission profile, a deviation between a static transmission profile of the positioner 1 and a previously known ideal transmission profile can be mapped. An ideal positioner 1 may have a static transmission function in the form of a diagonal straight line with a constant slope 1, wherein a positioner-specific modulated control variable u* would be equal to the received control variable u. Real positioners 1 may in particular deviate from an ideal behavior within a permissible tolerance range. The all-relationship of such a permissible deviation communicates its static transmission profile increasingly the accuracy of the virtual image 40/141. In the following, the term for virtual imaging would be used throughout for simplicity, wherein it should be clear that the virtual imaging described may optionally be implemented as a virtual mapping 141 by the computing arrangement of the process computer 103 or as a simulation module 40 of the positioner 1.

The second calculation section 420 of the virtual image of the positioner 1 can in an exemplary design subject the dynamics of the positioner 1 to a time response starting from the control variable u with the intermediate result u*, which can be realized, for example, by a first-order delay element as shown here. It is conceivable to provide more complex, in particular non-linear transmission functions concerning the time behavior.

The third calculation section 430 can optionally be used to introduce a possibly relevant dead time T_{D} into the virtual image of the positioner 1. Apart from a time shift corresponding to the dead time T_{D}, an intermediate value x̅ determined by the second calculation section 420 can be transferred unchanged in value to a further intermediate value x̅.

The fourth proposed calculation section 440 for quantification respectively differentiation in the exemplary virtual image of a positioner shown in FIG. 4 can be used to represent so-called non-reachable states. For example, a positioner 1 may provide a discrete, for example, electromagnetic drive, for example a stepper motor, which may exclusively assume certain discrete positions.

Another example may concern a positioner 1 with a frictional actuation of the control valve 3 with the particularly pneumatic actuator 5, in which, due to elasticity and/or friction on the powertrain, starting from a fixed starting point by the so-called stick-slip effect, starting from a stationary starting position, a certain minimum travel (jerk-slip or breakaway) initially characterizes the real behavior of the positioner 1. In particular for a positioner 1 with a pneumatic actuator 5, the so-called friction corridor can be relevant for the accuracy of the virtual image of the positioner. The description of the friction corridor can be implemented using an absolute or a relative step or stair function. A step height q can be defined as simulation parameter θ with respect to the discretization or quantization. The step height q can describe a uniformly divided absolute quantification of, for example, a stair function, or the width of a hysteresis-like one in a friction-controlled pneumatic actuator.

The features of the individual embodiments of the present disclosure may be provided in any combination in further embodiments of the present disclosure, and the present disclosure is not limited to any particular or isolated feature combination of embodiments.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects, but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

### REFERENCE LIST

1 positioner
3 control valve
5 actuator
7 positioner electronics
13 sensor
30 regulating module
40 simulation module (simulator)
50 adaptation module (adapter)
70 computing device (computer)
71 signal receiving interface
72 regulating variable input
73 signal output interface
74 control signal output
75 processor
76 memory
77 display unit
100 process plant
101 control station computer
103 process computer
104 process
107 signal transmission line
111 active field device
113 passive field device
130 process control
140 reference model
141 virtual image
150 adaptation logic
400 virtual image
401 routine
410 calculation section
420 calculation section
430 calculation section
440 calculation section
b1, b2 operating mode
p control parameter
s control signal
T_{D} dead time
u control variable
u* intermediate result
x device regulating variable
x̅ intermediate result
x̅ intermediate result
\tilde{x} virtual signal response
y regulating variable
\tilde{y} virtual regulating variable
θ simulation parameter
θ_{R} reference simulation parameter
θ_{H} historical simulation parameter

1. A positioner for a process plant, comprising:
a control valve configured to adjust a process fluid flow of the process plant,
a pneumatic actuator configured to actuate the control valve, and
positioner electronics configured to provide a pneumatic control signal for the actuator based on a control variable, the positioner electronics including:
a signal receiving interface configured to receive the control variable,
a computer configured to determine at least one simulation parameter that characterizes a signal response of the positioner to the received control variable, and
a signal output interface configured to output the at least one simulation parameter.

2. The positioner according to claim 1, wherein:
the positioner electronics is configured to generate the pneumatic control signal further based on a supplied real signal response,
the computer includes a simulator that is configured to receive the control variable as an input value and the at least one simulation parameter, and calculate a virtual signal response corresponding to a real signal response in form of a device regulating variable based on the control variable and the at least one simulation parameter, and
the computer includes an adapter configured to determine a realistic simulation parameter with respect to the positioner.

3. The positioner according to claim 1, wherein the positioner electronics includes at least one data storage configured to store the at least one simulation parameter and at least one stored reference simulation parameter for the at least one simulation parameter.

4. The positioner according to claim 3, wherein the at least one data storage is further configured to store a plurality of historical simulation parameters determined at different times.

5. The positioner according to claim 1, wherein the computer is configured to:
calculate a virtual signal response of the positioner based on a received control variable and at least one historical simulation parameter or at least one reference simulation parameter, and
compare the calculated virtual signal response with a real signal response detected by the positioner using one or more sensors of the positioner.

6. Positioner according to claim 5, wherein the computer is configured to:
detect a deviation between the real detected signal response and the calculated virtual signal response in time dimension, amplitude, and/or rate of change, and
determine a current simulation parameter based on the deviation.

7. The positioner according to claim 1, wherein the positioner electronics are configured to output the at least one simulation parameter using the signal output interface in response to a detected deviation by the positioner electronics based on a comparison of the at least one simulation parameter with a historical simulation parameter or a reference simulation parameter.

8. The positioner according to claim 1, wherein the at least one simulation parameter is selected from: dead time, discretization, static control and/or regulation deviation, and/or characteristic curve and/or gradient.

9. The positioner according to claim 1, wherein the positioner electronics are configured to provide the pneumatic control signal based on the control variable according to a control and/or regulating structure, the at least one simulation parameter being output based on a changed control and/or regulating structure.

10. The positioner according to claim 9, wherein the at least one simulation parameter designates the control and/or regulating structure used by the positioner electronics based on a predefined classification.

11. The positioner according to claim 1, wherein the signal output interface and the signal receiving interface are connected with a common signal transmission line, the signal receiving interface being configured to receive the control variable using the signal transmission line and the signal output interface being configured to output the at least one simulation parameter using the signal transmission line.

12. The positioner according to claim 1, wherein the signal output interface comprises a display configured to optically output the at least one simulation parameter.

13. The positioner according to claim 1, wherein the signal output interface is configured to output the at least one simulation parameter with a transmission rate of not more than 1200 bit/s.

14. The positioner according to claim 1, wherein the computer comprises a simulator configured to perform a simulation to determine a virtual signal response based on a reference simulation parameter and/or at least one historical simulation parameter and the received control variable.

15. The positioner according to claim 1, wherein the computer further comprises an adapter configured to detect a deviation between a virtual signal response and a real signal response, the adapter being configured to generate an updated simulation parameter based the detected deviation between virtual signal response and real signal response.

16. A system comprising:
at least one positioner according to claim 1, and
a master display or central computer unit superior to the positioner, the master display or central computer unit are configured to perform a simulation with one or more realistic simulation parameters using a virtual image of the process plant, one or more parts of the process plant, or the positioner.

17. The system according to claim 16, comprising a signal transmission line configured to transmit the control variable from a process computer to the positioner, the signal output interface and the signal receiving interface being connected with the signal transmission line.
